(19) United States
(12) Patent Application Publication
(10) Pub. No.: US 2009/0283308 A1
(43) Pub. Date: Nov. 19, 2009

(54) Curable Resin Composition and Use Thereof

(76) Inventor: Atsushi Tsukamoto, Tokyo (JP)

Correspondence Address: BIRCH STEWART KOLASCH & BIRCH, PO BOX 747, FALLS CHURCH, VA, 22040-0747, US

(21) Appl. No.: 12/085,437

(22) PCT Filed: Nov. 27, 2006
(86) PCT No.: PCT/JP2006/323536

§ 371 Date: May 23, 2008

(30) Foreign Application Priority Data
Nov. 25, 2005 (JP) 2005-341186

(51) Int. Cl. H05K 1/02; B05D 5/00; B05D 3/00; B32B 27/04; B32B 37/10; C08L 83/04

(52) U.S. Cl. 174/258; 427/387; 428/446; 428/448; 156/163; 524/588

(57) ABSTRACT

A curable resin composition comprising an insulating polymer such as an alicyclic olefin polymer, a curing agent, and an inorganic filler, wherein the inorganic filler is silica particles whose surface is bound with 0.1 to 30% by weight, based on the weight of the silica particles, of an alkoxy group-containing silane-modified resin (I) whose weight average molecular weight is 2,000 or more; a shaped material formed by shaping the curable resin composition; and a multilayer printed circuit board obtained by thermally compressing and curing the shaped material on a substrate having a conductor layer on its surface to form an electrically insulating layer.

### TECHNICAL FIELD

The present invention relates to a curable resin composition and the use thereof. More specifically, the present invention relates to a curable resin composition having silica particles favorably dispersed therein with excellent film formability and which is suitably used for an electrically insulating layer in a printed circuit board and the like, a shaped material using this composition, a cured material obtained by curing the shaped material, and a laminated body having an electrically insulating layer with excellent thermal shock resistance.

### BACKGROUND ART

As the electronic equipments are further downsized and made multifunctional, there is also an increase in demand for even further densification of printed circuit boards that are used in the electronic equipments. A method for making a printed circuit board to be multilayered is known as a means for densifying printed circuit boards. A multilayered printed circuit board (hereinafter may be referred to as a “multilayer printed circuit board”) is obtained by laminating an electrically insulating layer on an inner layer substrate, which is formed from another electrically insulating layer and a conductor layer formed on the surface thereof, and forming another conductor layer on this electrically insulating layer. Several layers of electrically insulating layers and conductor layers can be laminated where necessary.

Multilayer printed circuit boards repeatedly expand and shrink by the increase in temperature due to the heat generated from a device or the substrate itself when energized and by the reduction in temperature when unenergized. For this reason, stress is generated between a metal wiring as a conductor layer and an electrically insulating layer formed in the periphery thereof due to the differences in their coefficients of thermal expansion or the like, and this may cause a connection failure or a disconnection in the metal wiring, a generation of cracks in the electrically insulating layer, or the like. The defects caused by the differences in the coefficients of thermal expansion may be reduced by reducing the coefficient of thermal expansion of the electrically insulating layer in order to make it closer to that of the metal wiring. In order to achieve this, the addition of an inorganic filler such as silica particles to the electrically insulating layer for reducing its coefficient of thermal expansion has been proposed. It should be noted here that such an electrically insulating layer is generally obtained by shaping a curable resin composition, which usually contains an insulating polymer, a curing agent and an inorganic filler, into a film-form or a sheet-form, and then curing it.

However, when silica particles were directly used as the inorganic filler without any surface treatment process, the dispersion of silica particles in the insulating polymer was heterogeneous and strength of the obtained electrically insulating layer reduced in some cases. Accordingly, it is proposed to subject silica particles to a surface treatment process for use. In Patent Document 1, a process to use silica particles whose surface is modified with an alkyl group for enhancing their interaction with a resin is disclosed. However, the resulting thermal shock resistance was still insufficient.

On the other hand, Patent Documents 2 and 3 disclose a method, in which an alkoxy group-containing silane-modified epoxy resin is used as an insulating polymer, and by sol-gel curing this resin to form a siloxane network, an electrically insulating layer is obtained as a cured material having gelated fine silica portions. However, the electrically insulating layer obtained by this method contained bubbles at times that were generated inside resulting in the reduction of surface smoothness.

### Patent Document 1: JP-A-H04-114065

### Patent Document 2: JP-A-2001-261776

### Patent Document 3: JP-A-2004-331787

### DISCLOSURE OF THE INVENTION

### Problem to be Solved by the Invention

An object of the present invention is to provide a curable resin composition having an inorganic filler excellently dispersed therein. Another object of the present invention is to provide a film-shaped or sheet-shaped material formed by shaping the composition, a cured material formed by curing the shaped material and which has excellent thermal shock resistance, and a laminated body and a multilayer printed circuit board having an electrically insulating layer formed from the cured material.

### Means for Solving Problem

As a result of intensive studies, the present inventor discovered the use of silica particles, to which a relatively small amount of an alkoxy group-containing silane-modified resin having a specific molecular weight is bound as an inorganic filler can solve the above problem. The present invention is accomplished based on this finding.

According to a first aspect of the present invention, a curable resin composition comprising an insulating polymer, a curing agent, and an inorganic filler is provided, in which the inorganic filler is silica particles whose surface is bound with 0.1 to 30% by weight, based on the weight of the silica particles, of an alkoxy group-containing silane-modified resin (I) whose weight average molecular weight is 2,000 or more.

The above-mentioned alkoxy group-containing silane-modified resin (I) is preferably an alkoxy group-containing silane-modified epoxy resin.

The above-mentioned insulating polymer is preferably an alicyclic olefin polymer.

The above-mentioned inorganic filler is preferably the silica particles to which the alkoxy group-containing silane-modified resin is bound using a wet dispersion method.

The above-mentioned curable resin composition is preferably a composition that further contains an organic solvent and is made into a varnish.

According to a second aspect of the present invention, a shaped material formed by shaping the above-mentioned curable resin composition is provided.

The above-mentioned shaped material is preferably film-shaped or sheet-shaped.

According to a third aspect of the present invention, a method for producing the above-mentioned shaped material which comprises a step where the above-mentioned curable resin composition that is made into a varnish is applied on a support followed by drying is provided.

According to a fourth aspect of the present invention, a cured material formed by curing the above-mentioned shaped material is provided.

According to a fifth aspect of the present invention, a laminated body and a method for producing the laminated body are provided. The laminated body is formed by laminating a substrate which has a conductor layer on its surface, and an electrically insulating layer formed from the above-mentioned cured material. The method for producing the laminated body comprises a step of thermally compressing and curing the above-mentioned shaped material on the substrate having a conductor layer on its surface to form the electrically insulating layer.

According to a sixth aspect of the present invention, a multilayer printed circuit board comprising the above-mentioned laminated body is provided.

### Effect of the Invention

Since the curable resin composition of the present invention has excellent dispersibility of the silica particles therein, the cured material formed by curing the composition, and the laminated body and the multilayer printed circuit board that use this cured material as an electrically insulating layer are excellent in terms of thermal shock resistance and the like.

The multilayer printed circuit board of the present invention can suitably be used as a semiconductor device such as a CPU and a memory in the electronic equipments such as computers and mobile phones, and as a substrate for other surface-mounted components.

### BEST MODE FOR CARRYING OUT THE INVENTION

The curable resin composition of the present invention comprises an insulating polymer, a curing agent and an inorganic filler.

The inorganic filler used in the present invention is silica particles whose surface is bound with 0.1 to 30% by weight, based on the weight of the silica particles, of an alkoxy group-containing silane-modified resin (I) whose weight average molecular weight is 2,000 or more.

By subjecting silica particles to a surface treatment using the aforementioned silane-modified resin (I), the silica particles will have a surface to which the silane-modified resin (I) is physically or chemically bound. When the inorganic filler is extracted with a solvent that can dissolve the silane-modified resin (I), no observation of extracted silane-modified resin (I) indicates that the silane-modified resin is bound to silica particles.

Shape of the inorganic filler used in the present invention is not limited as long as the filler is in a particulate form. However, a spherical shape is preferable in view of varnish fluidity. Volume average particle diameter of the inorganic filler is preferably 5 μm or less, more preferably 3 μm or less, and even more preferably 2 μm or less. When the volume average particle diameter exceeds 5 μm, the smoothness of the electrically insulating layer may be lost or the electrical insulating properties may be impaired.

Moreover, it is preferable to remove the particles having a particle diameter of 5 μm or more by a classification process, a filtration process, or the like before or after subjecting silica particles to a surface treatment. On the other hand, the volume average particle diameter of the inorganic filler is preferably 0.05 μm or more. When the volume average particle diameter is less than 0.05 μm, fluidity of the obtained varnish is impaired in some cases.

In addition, although the silica particles to be subjected to a surface treatment are not particularly limited, highly pure, spherical molten silica particles are preferable in view of their low impurity content.

The silane-modified resin (I) used in the present invention is a silane-modified resin containing an alkoxy group. Since the silane-modified resin (I) has an alkoxy group, it can react with the silanol group present on the surface of silica particles to form a siloxane bond.

The silane-modified resin containing an alkoxy group is obtained by the dealcoholization condensation reaction between a resin containing a hydroxyl group (base resin) and a partial condensate of alkoxysilane.

Examples of the base resin include epoxy resin, acrylic resin, polyurethane resin, polyamide resin, polyimide resin, and polyamide-imide resin. Of these, epoxy resin is preferable from the viewpoints of its compatibility with an insulating polymer and its reactivity.

An example of the epoxy resin includes a bisphenol-type epoxy resin obtained by the reaction between bisphenols and haloepoxides such as epichlorohydrin, or β-methylepichlorohydrin. Examples of the bisphenols include those obtained by the reaction between phenol and aldehydes or ketones such as formaldehyde, acetaldehyde, acetone, acetophenone, cyclohexanone, and benzophenone, and also those obtained by the oxidation of dihydroxyphenyl sulfide using a peracid or by the etherification reaction between hydroquinones. Additionally, a hydrogenated epoxy resin obtained by the hydrogenation of an epoxy resin having the above-mentioned bisphenol structure under an applied pressure can also be used. Above all, a bisphenol A-type epoxy resin in which bisphenol A is used as a bisphenol component is preferable.

In addition, a novolac type epoxy resin obtained by the glycidyl etherification of novolac can also be suitably used as a base resin.

Weight average molecular weight (Mw) of the silane-modified resin (I) is 2,000 or more, preferably 2,000 to 50,000, and more preferably 2,000 to 30,000. When Mw is too low, the effect of improving thermal shock resistance due to the surface treatment will be small. When Mw is too high, solubility with respect to a solvent may decline or compatibility with an insulating polymer may deteriorate. As a result, there is a possibility that dispersibility will decline or the effect of improving mechanical properties due to the surface treatment will be insufficient.

The inorganic filler used in the present invention is silica particles where the afore-mentioned silane-modified resin (I) is bound in the amount of 0.1 to 30% by weight, preferably 0.5 to 20% by weight, and more preferably 1 to 15% by weight.

Amount of the bound silane-modified resin (resin binding amount) is a ratio of the amount of silane-modified resin that is bound to the surface of silica particles relative to 100 parts by weight of silica particles before being subjected to a surface treatment and this can be determined by the following formula.

Resin binding amount(% by weight)=(amount of silane-modified resin used in surface treatment−amount of unbound silane-modified resin)/amount of silica particles before surface treatment×100

Note that the amount of unbound silane-modified resin can be determined from the amount of the silane-modified resin (I) in a supernatant obtained by first preparing a slurry due to the mixing of an inorganic filler after the surface treatment with an extracting solvent, and then repeating an operation in which the resulting slurry is centrifuged to remove the supernatant. A solvent capable of dissolving the silane-modified resin (I) is used as an extracting solvent.

Preferable range of the resin binding amount of the silane-modified resin (I) depends also on the particle diameter of silica particles. Due to a heating treatment when curing the curable resin composition to be obtained, a sol-gel reaction or a dealcoholization reaction may take place forming a higher network structure of siloxane (fine silica). However, when the resin binding amount is too large, a large amount of alcohol with a low boiling point is produced during these reactions. Accordingly, bubbles are generated inside the obtained film-shaped or sheet-shaped material or the surface smoothness of the material may deteriorate. On the other hand, when the resin binding amount is too small, the dispersion of inorganic filler in the curable resin composition will be insufficient resulting in high viscosity of the obtained varnish, and the deterioration of thermal shock resistance of the obtained film-shaped or sheet-shaped material.

The ratio of the silane-modified resin (I) bound with silica particles is 70% by weight or more, preferably 80% by weight or more, and more preferably 90% by weight or more, with respect to the amount of the silane-modified resin (I) used in the surface treatment. When the ratio is too low, a large amount of silane-modified resin (I) will be present in an unbound form, and thus phase separation may occur when the composition is made into a varnish or bubbles may be generated when the composition is made into a film-shaped material.

The method for subjecting silica particles to a surface treatment is not limited as long as the silane-modified resin (I) can be bound to the surface of silica particles. However, a wet dispersion method in which silica particles, the silane-modified resin (I) and an organic solvent are mixed to prepare a slurry of silica particles is preferable. In the wet dispersion method, the slurry of silica particles may contain other components that constitute a curable composition such as an insulating polymer and a curing agent. However, since these other components may reduce the efficiency of surface treatment by, for example, adsorbing to silica particles, it is preferable to carry out the surface treatment under a condition where other components are substantially absent.

In the wet dispersion method, the organic solvent for preparing the slurry of silica particles may be any organic compound that is in a liquid state under normal temperature and pressure conditions, and it can appropriately be selected in accordance with the types of silica particles and silane-modified resin (I).

Examples of the organic solvent include aromatic hydrocarbon organic solvents such as toluene, xylene, ethylbenzene, and trimethylbenzene; aliphatic hydrocarbon organic solvents such as n-pentane, n-hexane, and n-heptane; alicyclic hydrocarbon organic solvents such as cyclopentane and cyclohexane; halogenated hydrocarbon organic solvents such as chlorobenzene, dichlorobenzene, and trichlorobenzene; and ketone organic solvents such as methyl ethyl ketone, methyl isobutyl ketone, cyclopentanone, and cyclohexanone.

In addition, it is preferable to use the organic solvent after removing water contained in the organic solvent by means of distillation, adsorption, drying, or the like.

Temperature during the surface treatment is usually 20 to 100° C., preferably 30 to 90° C., and more preferably 40 to 80° C. When the temperature during the surface treatment is too low, the viscosity of slurry will be high leading to insufficient crushing of silica particles, and in some cases, the aggregates of silica particles containing silica particles with untreated surface may be produced. Moreover, it is not preferable since the alkoxy group of the silane-modified resin (I) is hydrolyzed by the mixing of water due to condensation, and thus the surface treatment may become insufficient. On the other hand, when the temperature during the surface treatment is too high, vapor pressure of the solvent contained in the slurry will be high. Accordingly, it is not preferable since a pressure-resistant container may be required or a problem of the decline in sanitation may arise due to the solvent vaporization. The temperature during the surface treatment can appropriately be selected within a temperature range, in which the silane-modified resin (I) reacts with the surface of silica particles efficiently without self-reaction, and which is also equal to or lower than the boiling point of the solvent used.

Processing time of the surface treatment is usually 1 minute to 300 minutes, preferably 2 minutes to 200 minutes, and more preferably 3 minutes to 120 minutes.

An apparatus used in the surface treatment is not limited as long as it can bring silica particles into contact with the silane-modified resin (I) under the above treatment conditions. Examples thereof include an agitator using a magnetic stirrer, a Hobart mixer, a ribbon blender, a high-speed homogenizer, a disper, a planetary stirring machine, a ball mill, a bead mill, and an ink roll. Among them, it is preferable to carry out the surface treatment while using a bead mill or an ultrasonic dispersing apparatus for crushing the aggregated silica particles in view of sufficiently dispersing silica particles.

The insulating polymer used in the present invention is a polymer having electrical insulating properties. Volume resistivity of the insulating polymer as measured in accordance with ASTM D257 is preferably 1×10⁸ Ω·cm or more, and more preferably 1×10¹⁰ Ω·cm or more. Examples of the insulating polymer include an epoxy resin, a maleimide resin, an acrylic resin, a methacrylic resin, a diallyl phthalate resin, a triazine resin, an alicyclic olefin polymer, an aromatic polyether polymer, a benzocyclobutene polymer, a cyanate ester polymer, a liquid crystal polymer, and a polyimide resin. Among them, an alicyclic olefin polymer, an aromatic polyether polymer, a benzocyclobutene polymer, a cyanate ester polymer, and a polyimide resin are preferable, and an alicyclic olefin polymer and an aromatic polyether polymer are more preferable, and an alicyclic olefin polymer is particularly preferable.

In the present invention, the phrase “alicyclic olefin polymer” is a generic term that includes homopolymers and copolymers of alicyclic olefins, the derivatives thereof (such as hydrogenated products), and the polymers having an equivalent structure to that of the above olefin polymers and the derivatives thereof. Additionally, the mode of polymerization may be addition polymerization or ring opening polymerization.

Specific examples of the polymers include a ring opening polymer formed of a monomer having a norbornene ring such as 8-ethyl-tetracyclo[4.4.0.1^{2,5}.1^{7,10}]-dodeca-3-ene (hereinafter referred to as a norbornene-derived monomer) and a hydrogenated product thereof, an addition polymer formed of a norbornene-derived monomer, an addition copolymer of a norbornene-derived monomer and a vinyl compound, an addition polymer of monocyclic cycloalkene, an alicyclic conjugated diene polymer, and a vinyl alicyclic hydrocarbon polymer and a hydrogenated product thereof. Moreover, the polymers also include those having an equivalent structure to that of alicylic olefin polymers as a result of the formation of an alicyclic structure due to the hydrogenation after polymerization such as an aromatic olefin polymer whose aromatic ring is hydrogenated. Among them, a ring opening polymer formed of a norbornene-derived monomer and a hydrogenated product thereof, an addition polymer formed of a norbornene-derived monomer, an addition copolymer of a norbornene-derived monomer and a vinyl compound, and an aromatic olefin polymer whose aromatic ring is hydrogenated are preferable, and a hydrogenated product of a ring opening polymer formed of a norbornene-derived monomer is particularly preferable. The method for polymerizing alicyclic olefins and aromatic olefins and the method for hydrogenation, which is carried out if necessary, are not particularly limited and they can be performed in accordance with a known method.

The alicyclic olefin polymer is preferably one that further contains a polar group. Examples of the polar group include a hydroxyl group, a carboxyl group, an alkoxyl group, an epoxy group, a glycidyl group, an oxycarbonyl group, a carbonyl group, an amino group, an ester group and a carboxylic anhydride group. Among them, a carboxyl group and a carboxylic anhydride group are particularly suitable. A method for obtaining the alicyclic olefin polymer having a polar group is not particularly limited. Examples of the method include a method (i) in which an alicyclic olefin monomer containing a polar group is homopolymerized, or copolymerized with another monomer that is copolymerizable therewith; and a method (ii) in which a polar group is introduced to an alicyclic olefin polymer containing no polar groups by the graft-bonding of a carbon-carbon unsaturated bond-containing compound having a polar group under the presence of, for example, a free radical initiator.

As a curing agent used in the present invention, common curing agents such as an ionic curing agent, a free radical curing agent, or a curing agent having both ionic and radical characteristics can be used. In particular, polyepoxy compounds such as a glycidyl ether type epoxy compound such as bisphenol A bis(propylene glycol glycidyl ether) ether, an alicyclic epoxy compound, and a glycidyl ester type epoxy compound are preferable. Moreover, in addition to the epoxy compound, it is also possible to use a non-epoxy curing agent having a carbon-carbon double bond and contributing to a crosslinking reaction such as 1,3-diallyl-5-[2-hydroxy-3-phenyloxy propyl]isocyanurate.

In the curable resin composition of the present invention, the amount of curing agent used is usually within a range of 1 to 100 parts by weight, preferably 5 to 80 parts by weight, and more preferably 10 to 50 parts by weight, with respect to 100 parts by weight of the insulating polymer.

Additionally, the amount of inorganic filler used is preferably 3 to 300 parts by weight, more preferably 5 to 150 parts by weight, and even more preferably 7 to 100 parts by weight, when the total amount of the insulating polymer and the curing agent is 100 parts by weight.

The curable resin composition of the present invention may further contain a curing accelerator or a curing auxiliary. For example, when a polyepoxy compound is used as a curing agent, curing accelerators or curing auxiliaries such as tertiary amine compounds including 1-benzyl-2-phenylimidazole and trifluorinated boron complex compounds are preferably used in order to accelerate the curing reaction. The amount of a curing accelerator and a curing auxiliary in total is usually 0.01 to 10 parts by weight, preferably 0.05 to 7 parts by weight, and more preferably 0.1 to 5 parts by weight, relative to 100 parts by weight of a curing agent.

The curable resin composition of the present invention may contain, in addition to the respective components described above and when desired, a flame retardant, a laser processing improver, a soft polymer, a heat resistant stabilizer, a weather resistant stabilizer, an age resistor, a leveling agent, an antistatic agent, a slip agent, an antiblocking agent, an antifogging agent, a lubricant, a dye, a pigment, a natural oil, a synthetic oil, a wax, an emulsion, an ultraviolet absorber, or the like.

The curable resin composition of the present invention is preferably used as a varnish which is formed by further containing an organic solvent in addition to the above-mentioned respective components. As an organic solvent, all the organic solvents exemplified as those used in the surface treatment of silica particles by the wet dispersion method can be used. Among these organic solvents, a mixed organic solvent, in which a non-polar organic solvent such as an aromatic hydrocarbon organic solvent and an alicyclic hydrocarbon organic solvent, and a polar organic solvent such as a ketone organic solvent are mixed, is preferable. Although the mixing ratio between the non-polar organic solvent and the polar organic solvent can be selected appropriately, the ratio is, in terms of weight ratio, usually within a range of 5:95 to 95:5, preferably 10:90 to 90:10, and more preferably 20:80 to 80:20. By using such a mixed organic solvent, it is possible to obtain a film-shaped or a sheet-shaped material which can excellently be embedded into a fine interconnection when forming the electrically insulating layer without generating bubbles or the like.

The amount of organic solvent used is appropriately selected so that the solid content of a varnish will exhibit a suitable viscosity for application. The amount of organic solvent in the varnish is usually 20 to 80% by weight and preferably 30 to 70% by weight.

The method for obtaining the curable resin composition of the present invention is not particularly limited and it is only necessary to mix the abovementioned respective components following an ordinary method. In terms of the temperature when mixing the respective components, it is preferable to conduct the operation at a temperature where the reaction by the curing agent does not adversely affect the workability, and it is more preferable to conduct the operation at a temperature of no more than the boiling point of the organic solvent used in the mixing process from the safety point of view.

Examples of the apparatus used in the mixing process include one that combines a stirring bar and a magnetic stirrer, a high-speed homogenizer, a disper, a planetary stirring machine, a biaxial stirring machine, a ball mill, a bead mill, attritor mill and a three roll mill.

The shaped material of the present invention is formed by shaping the curable resin composition of the present invention described above. Shaping method is not particularly limited and shaping may be carried out by an extrusion method or a pressing method. However, it is preferable to carry out the shaping process by a solution casting method in view of operational ease. The solution casting method is a method for obtaining a shaped material with a support by applying a curable resin composition that is in a varnish form onto the support and removing the organic solvent by drying.

Examples of the support to be used in the solution casting method include a resin film and a metal foil. As a resin film, a thermoplastic resin film is usually used and specific examples thereof include a polyethylene terephthalate film, a polypropylene film, a polyethylene film, a polycarbonate film, a polyethylene naphthalate film, a polyallylate film, and a nylon film. Among these resin films, the polyethylene terephthalate film and the polyethylene naphthalate film are preferable from the viewpoints of heat resistance, chemical resistance, and release properties after lamination. Examples of the metal foil include a copper foil, an aluminum foil, a nickel foil, a chromium foil, a gold foil, and a silver foil. A copper foil, especially an electrolytic copper foil or a rolled copper foil is suitable for its favorable electrical conductivity and low cost. Although thickness of the support is not particularly limited, it is usually 1 μm to 200 μm, preferably 2 μm to 100 μm, and more preferably 3 μm to 50 μm from the viewpoint of workability and the like.

Examples of the application method include dip coating, roll coating, curtain coating, die coating, and slit coating. Additionally, conditions for drying are appropriately selected depending on the types of organic solvent and the drying temperature is usually 20 to 300° C., preferably 30 to 200° C., and more preferably 70 to 140° C. Drying time is usually 30 seconds to 1 hour and preferably 1 minute to 30 minutes.

The shaped material of the present invention is preferably film-shaped or sheet-shaped. Its thickness is usually 0.1 to 150 μm, preferably 0.5 to 100 μm, and more preferably 1.0 to 80 μm. Note that when a film-shaped or a sheet-shaped material is required solely, the film-shaped or the sheet-shaped material is formed on a support by the abovementioned method and thereafter the film is separated from the support.

Alternatively, it is also possible to form a prepreg by impregnating a substrate of fiber such as an organic synthetic fiber and a glass fiber, with the curable resin composition of the present invention in a varnish form.

The cured material of the present invention is formed by curing the abovementioned shaped material of the present invention. Curing of the shaped material is usually conducted by heating the shaped material. Curing conditions are appropriately selected in accordance with the composition of curable resin composition. Curing temperature is usually 30 to 400° C., preferably 70 to 300° C., and more preferably 100 to 200° C. Curing time is 0.1 to 5 hours and preferably 0.5 to 3 hours. Heating method is not particularly limited and, for example, an electric oven may be used.

The laminated body of the present invention is formed by laminating a substrate having a conductor layer on the surface thereof (hereinafter referred to as an “inner layer substrate”) and an electrically insulating layer formed of the cured material of the present invention. The inner layer substrate has a conductor layer on the surface of an electrically insulating substrate. The electrically insulating substrate is formed by curing a curable resin composition containing a known electrically insulating material. Examples of the electrically insulating material include an alicyclic olefin polymer, an epoxy resin, a maleimide resin, an acrylic resin, a methacrylic resin, a diallyl phthalate resin, a triazine resin, polyphenyl ether, and glass. In addition, the cured material of the present invention can also be used. These materials may also be those that further contain a glass fiber, a resin fiber, or the like for the sake of strength improvement.

The conductor layer usually is, although not particularly limited, a layer containing an interconnection formed of a conductive material such as an electrically conductive metal, and the layer may further contain various circuits. Configuration, thickness, or the like of the interconnection and the circuit is not particularly limited. Specific examples of the inner layer substrate include a printed wiring board and a silicon wafer substrate. Thickness of the inner layer substrate is usually 20 μm to 2 mm, preferably 30 μm to 1.5 mm, and more preferably 50 μm to 1 mm.

It is preferable that the conductor layer surface of the inner layer substrate be subjected to a pretreatment in order to enhance adhesive properties with the electrically insulating layer. A known technique can be applied for the pretreatment method without any particular limitation. Examples thereof include an oxidation treatment method in which a strong alkali oxidizing solution is brought into contact with the conductor layer surface, thereby forming a copper oxide layer on the conductor surface to be roughened if the conductor layer is formed of copper; a method in which the conductor layer surface is oxidized by the aforementioned method and thereafter is reduced using sodium borohydride, formalin, or the like; a method in which plating is deposited in the conductor layer for roughening; a method in which an organic acid is brought into contact with the conductor layer, thereby eluting the copper grain boundary for roughening; and a method in which a primer layer is formed in the conductor layer using a thiol compound, a silane compound, or the like. Among these methods, the method in which an organic acid is brought into contact with the conductor layer, thereby eluting the copper grain boundary for roughening, and the method in which a primer layer is formed using a thiol compound, a silane compound, or the like are preferable from the viewpoint of easy maintenance of the form of fine wiring patterns.

Examples of the method for obtaining the laminated body of the present invention include a method (A) in which the curable resin composition of the present invention in a varnish form is first applied on the inner layer substrate and then the organic solvent is removed to obtain the shaped material of the present invention, followed by the curing of the shaped material; and a method (B) in which the film-shaped or the sheet-shaped material of the present invention is first laminated on the inner layer substrate and subsequently they are adhered by a thermocompression process or the like and then further cured. The method (B) is preferable from the viewpoints of high smoothness of the obtained electrically insulating layer and the easiness of multilayer formation. Thickness of the electrically insulating layer to be formed is usually 0.1 to 200 μm, preferably 1 to 150 μm, and more preferably 10 to 100 μm.

In the method (A), it is the same as the method for obtaining the shaped material of the present invention by the solution casting method, except that the inner layer substrate is used instead of a support. The method for applying the curable resin composition in a varnish form on the inner layer substrate and the conditions for removing the organic solvent are both the same as those described earlier. The laminated body is obtained by curing the obtained shaped material by a heating process or a light irradiation process. When the heating process is employed, the curing condition in terms of temperature is usually 30 to 400° C., preferably 70 to 300° C., and more preferably 100 to 200° C. Heating time is usually 0.1 to 5 hours and preferably 0.5 to 3 hours. When necessary, the curing process may be carried out after drying the coating film and smoothing the surface of the shaped material using a pressing machine or the like.

In the method (B), specific examples of the thermocompression method include a method in which the film-shaped or the sheet-shaped material is superimposed on the inner layer substrate so as to contact the conductor layer therein and then they are subjected to a contact bonding (lamination) process by applying heat and pressure at the same time using a pressing machine such as a pressure laminator, a press, a vacuum laminator, a vacuum press, and a roll laminator, thereby forming the electrically insulating layer on the conductor layer. By employing the thermocompression process, bonding can be achieved without any substantial presence of gaps in the interface between the conductor layer in the surface of the inner layer substrate and the electrically insulating layer. When the shaped material with a support is used, curing is usually carried out after separating the support. However, it is also possible to directly subject the material to the thermocompression and curing processes without the support separation. In particular, when a metal foil is used as the support, since the adhesive properties between the obtained electrically insulating layer and the metal foil are also enhanced, the metal foil can be used directly as a conductor layer of the multilayer printed circuit board described later.

Temperature during the thermocompression operation is usually 30 to 250° C. and preferably 70 to 200° C. The pressure applied to the shaped material is usually 10 kPa to 20 MPa and preferably 100 kPa to 10 MPa. Time for the thermocompression process is usually 30 seconds to 5 hours and preferably 1 minute to 3 hours. Additionally, it is preferable that the thermocompression process be carried out under reduced pressure in order to improve embedding properties of the wiring patterns and to suppress the generation of bubbles. The atmospheric pressure where the thermocompression process is carried out is usually 1 Pa to 100 kPa and preferably 10 Pa to 40 kPa.

The laminated body of the present invention is produced by first curing the shaped material that is thermally compressed and then forming the electrically insulating layer. Curing is usually conducted by heating the entire substrate where the shaped material is laminated on the conductor layer. Curing can be carried out simultaneously with the aforementioned thermocompression operation. Moreover, curing may also be carried out after conducting the thermocompression operation first under a condition where curing does not take place, in other words, at a relatively low temperature for a short period of time. 2 or more of the shaped materials may be brought into contact with the inner layer substrate on the conductor layer thereof to be bonded for lamination in order to improve the flatness of the electrically insulating layer or to increase the thickness of the electrically insulating layer.

The multilayer printed circuit board of the present invention contains the abovementioned laminated body. Although the laminated body of the present invention can be used as a monolayer printed circuit board, it is preferably used as a multilayer printed circuit board where a conductor layer is further formed on the aforementioned electrically insulating layer. In the production of the laminated body, when a resin film is used as a support of the shaped material, the multilayer printed circuit board of the present invention can be produced by forming a conductor layer on the electrically insulating layer using a plating or the like after separating the resin film. In addition, when a metal foil is used as a support of the shaped material, a conductor layer can be formed by pattern etching the metal foil using a known etching method.

Insulation resistance between layers in the multilayer printed circuit board of the present invention is preferably 10⁸Ω or more as measured based on a measurement method specified in JIS C 5012. Moreover, it is more preferable that the insulation resistance between layers in a state where a direct current voltage of 10 V is applied and after being left to stand under the conditions of a temperature of 130° C. and a humidity of 85% is 10⁸Ω or more.

In the method for forming a conductor layer by plating, an opening for forming a via hole is first formed in the electrically insulating layer. Then a metal thin film is formed on the surface of this electrically insulating layer and on the inner wall surface of the opening for forming a via hole using a drying process (dry plating method) such as a sputtering process, and a plating resist is formed on the metal thin film. Then a plating film is further formed thereon using a wet plating process such as an electrolytic plating process. By subsequently removing this plating resist and conducting an etching process, a second conductor layer formed of the metal thin film and the electrolytic plating film can be formed. In order to enhance adhesion between the electrically insulating layer and the second conductor layer, the surface of the electrically insulating layer may be brought into contact with a solution of permanganic acid, chromic acid, or the like, or may be subjected to a plasma treatment or the like.

A method to form the opening for forming a via hole, which connects the first conductor layer and the second conductor layer, on the electrically insulating layer is not particularly limited. The method is conducted by, for example, a physical treatment such as a drilling process, a laser treatment, and a plasma etching process. The method employing a laser such as a carbon dioxide laser, an excimer laser, and a UV-YAG laser is preferable from the viewpoint that finer via holes can be formed without impairing the properties of the electrically insulating layer.

By using the multilayer printed circuit board obtained as described so far as a next inner layer substrate and repeating the abovementioned processes for forming the electrically insulating layer and the conductor layer, further lamination can be carried out, thereby making it possible to obtain a desired multilayer printed circuit board. Moreover, in the abovementioned printed circuit board, part of the conductor layer may be a metal power source layer, a metal ground layer, or a metal shield layer.

### EXAMPLES

The present invention will be described below in further details using Examples and Comparative Examples. However, the present invention is not limited to these Examples. The terms “parts” and “%” used in Examples and Comparative Examples are based on weight unless stated otherwise.

Definitions and evaluation methods for the respective properties are as follows.

### (1) Molecular Weight of Polymer

Number average molecular weight (Mn) and weight average molecular weight (Mw) of the alkoxy group-containing silane-modified resin and the insulating polymer were measured by gel permeation chromatography (GPC) and determined as a polystyrene equivalent value. As developing solvents, toluene was used for measuring the molecular weight of polymers with no polar group and tetrahydrofuran was used for measuring the molecular weight of polymers containing a polar group.

### (2) Content of Maleic Anhydride Group

The content refers to the ratio of the number of moles of maleic anhydride groups contained in a polymer to the total number of monomer units in the polymer. The content was determined by ¹H-NMR spectroscopy.

### (3) Glass Transition Temperature (Tg) of Polymer

The temperature was measured by differential scanning calorimetry (DSC) method at a rate of temperature increase of 10° C./min.

### (4) Resin Binding Amount

Part of the slurry in which an inorganic filler was dispersed was sampled and this sample was then centrifuged to remove supernatant. Moreover, the organic solvent used in the surface treatment was added thereto and the processes of centrifugation and removal of supernatant were repeated. The amount of silane-modified resin (I) extracted in the supernatant was defined as the amount of silane-modified resin (I) that did not bind to silica particles. This amount was subtracted from the amount of silane-modified resin (I) used in the surface treatment to determine the resin binding amount.

### (5) Viscosity of Curable Varnish

Viscosity of the varnish containing an inorganic filler was measured at 25° C. using an E type viscometer and was defined as an indicator of dispersion of the inorganic filler. The lower varnish viscosity, the better inorganic filler was dispersed.

### (6) Number of Defects

In a 10 cm×10 cm region randomly selected from the electrically insulating layer of the laminated body obtained by using a film-shaped material, the number of bubbles was measured by visual inspection and was evaluated using the following criteria.

A: 2 or less bubbles

B: 3 to 10 bubbles

C: 11 to 20 bubbles

D: 21 or more bubbles

### (7) Thermal Shock Test

50 mm×50 mm-sized pieces were cut out from the laminated bodies obtained in Examples and Comparative Examples, and on the electrically insulating layer therein, a 20 mm square silicon wafer having a thickness of about 400 μm was adhered using an underfill agent to form a laminated body with a silicon wafer. By using the laminated body with a silicon wafer, a thermal shock test was carried out using a liquid phase method under the conditions where one cycle of the process was composed of a low temperature condition (−65° C.×5 minutes) and a high temperature condition (+150° C.×5 minutes). When the process of 500 cycles was completed, cracks generated on the electrically insulating layer were observed using a microscope and the number thereof was measured.

### Example of Silica Surface Treatment 1

A 70% solution of a methoxy group-containing silane-modified epoxy resin derived from a bisphenol A type epoxy resin as a base resin was prepared as the silane-modified resin (I). This methoxy group-containing silane-modified epoxy resin was “Compoceran E102” (trade name: manufactured by Arakawa Chemical Industries, Ltd.) and the Mw thereof was 10,000. The solvent used for preparing the solution was a mixed solvent of methyl ethyl ketone (MEK) and methanol.

A uniform slurry was prepared by mixing 70 parts of silica particles having a volume average particle diameter of 0.5 μm, 22.5 parts of xylene, 7.5 parts of cyclopentanone, and 5 parts of the 70% solution of a methoxy group-containing silane-modified epoxy resin.

A slurry A was obtained by filling a 250 parts by volume of a zirconia pot with 80 parts of the abovementioned slurry and 360 parts of zirconia beads having a diameter of 0.3 mm and stirring for 3 minutes using a planetary ball mill (P-5: manufactured by Fritsch GmbH) at a centrifugal acceleration of 5 G (a disc rotational frequency (revolution speed) of 200 rpm and a pot rotational frequency (rotation velocity) of 434 rpm). When part of the slurry A was sampled and the resin binding amount to the obtained inorganic filler was measured, 90% of the silane-modified resin (I) used was bound to silica particles and the resin binding amount was 4.5%. Results are shown in Table 1.

TABLE 1

| | | Example of surface treatment | | | |
|---|---|---|---|---|---|
| | | 1 | 2 | 3 | 4 |
| Solution | Product | Compoceran | Compoceran | Compoceran | Compoceran |
| of | number | E102 | E112M | E113M | E103 |
| silane | Base resin | Bisphenol A | Novolac | Novolac | Bisphenol A |
| modified | | type epoxy | type epoxy | type epoxy | type epoxy |
| resin | | resin | resin | resin | resin |
| | Mw | 10,000 | 3,200 | 5,000 | 9,000 |
| | Solvent | MEK/ | MEK/ | MIBK/ | MEK |
| | | methanol | methanol | toluene | |
| | Conc. (%) | 70 | 57 | 54 | 60 |

| | | | | |
|---|---|---|---|---|
| Amount used (% | 5 | 5 | 5 | 5 |
| solid content | | | | |
| relative to silicon | | | | |
| particles) | | | | |
| Slurry | A | B | C | D |
| Resin binding | 4.5 | 4.7 | 4.6 | 4.4 |
| amount (%) | | | | |

### Examples of Silica Surface Treatment 2 to 4

Slurrys B to D were obtained in the same manner as that of the example of silica surface treatment 1 except that the types of the silane-modified resin (I) and the amount thereof used were those shown in Table 1. Measurement results of the resin binding amount to inorganic filler for each slurry were shown in Table 1. Note that all the silane-modified resins (I) used were manufactured by Arakawa Chemical Industries, Ltd.

### Example of Silica Surface Treatment 5

A slurry E was obtained in the same manner as that of the example of silica surface treatment 1 except that one part of 3-glycidoxypropyltrimethoxysilane (molecular weight: 236) was used instead of the silane-modified resin (I).

### Preparation Example of Slurry of Silica with Untreated Surface

A slurry F was obtained in the same manner as that of the example of silica surface treatment 1 except that the silane-modified resin (I) was not used.

### Production Example 1

100 parts of a hydrogenated product of a ring opening polymer of 8-ethyl-tetracyclo[4.4.0.1^{2,5}.1^{7,10}]-dodeca-3-ene (Mn=31,200, Mw=55,800, Tg=140° C., and hydrogenation rate of 99% or more), 40 parts of maleic anhydride, and 5 parts of dicumyl peroxide were dissolved in 250 parts of t-butylbenzene and the reaction was carried out at 140° C. for 6 hours. The obtained solution of reaction product was added into 1,000 parts of isopropyl alcohol to precipitate the reaction product, and the precipitate was vacuum dried at 100° C. for 20 hours to obtain a maleic anhydride-modified hydrogenated polymer. This modified hydrogenated polymer had Mn of 33,200, Mw of 68,300, and Tg of 170° C. The content of maleic anhydride group was 25 mol %.

### Production Example 2

100 parts of the modified hydrogenated polymer obtained in Production Example 1 as an insulating polymer, 37.5 parts of bisphenol A bis(propylene glycol glycidyl ether) ether and 12.5 parts of 1,3-diallyl-5-[2-hydroxy-3-phenyloxypropyl]isocyanurate as curing agents, 6 parts of dicumyl peroxide and 0.1 parts of 1-benzyl-2-phenylimidazole as curing accelerators, 5 parts of 2-[2-hydroxy-3,5-bis(α,α-dimethyl benzyl)phenyl]benzotriazole as a laser processing improver, and 1 part of 1,3,5-tris(3,5-di-tert-butyl-4-hydroxybenzyl)-1,3,5-triazine-2,4,6-trione as a heat stabilizer were dissolved in a mixed organic solvent formed of 147 parts of xylene and 49 parts of cyclopentanone to obtain a varnish A.

### Production Example 3

100 parts of the modified hydrogenated polymer obtained in Production Example 1, 30 parts of polyoxypropylene bisphenol A diglycidyl ether (EP-4000S: manufactured by Adeka Corporation) as a curing agent, 10 parts of liquid polybutadiene (Nisseki polybutadiene B-1000: manufactured by Nippon Oil Corporation) as a soft polymer, 0.1 parts of 1-benzyl-2-phenylimidazole as a curing accelerator, 5 parts of 2-[2-hydroxy-3,5-bis(α,α-dimethylbenzyl) phenyl]benzotriazole as a laser processing improver, and 1 part of 1,3,5-tris(3,5-di-tert-butyl-4-hydroxy benzyl)-1,3,5-triazine-2,4,6-trione as a heat stabilizer were dissolved in a mixed organic solvent formed of 147 parts of xylene and 49 parts of cyclopentanone to obtain a varnish B.

### Example 1

The slurry A was added to the varnish A obtained in Production Example 2 so that the amount of inorganic filler will be 30 parts relative to 100 parts of the modified hydrogenated polymer contained in the varnish, and the resultant was stirred for 3 minutes using a planetary stirring machine as in the Example of silica surface treatment 1 to obtain a curable varnish. Measurement results of the viscosity of the obtained curable varnish are shown in Table 2. This curable varnish was applied on a 300 mm square polyethylene naphthalate film (support film) having a thickness of 50 μm and the resultant was then dried under nitrogen atmosphere in an oven at 60° C. for 10 minutes and subsequently dried at 80° C. for 10 minutes to obtain a film-shaped material having a thickness of 40 μm on the support film.

This film-shaped material was mounted on a copper-clad laminate as an inner layer substrate so that the support film will be the uppermost surface and they were vacuum pressed for 5 minutes at a temperature of 120° C. and a pressure of 1 MPa. The support film was removed and the shaped material was cured by heating under nitrogen atmosphere in an oven at 180° C. for 120 minutes to obtain a copper-clad laminate with a cured material which is the laminated body of the present invention. Note that a double-sided copper-clad laminate “CCL-HL830” (trade name: having a thickness of 0.8 mm and a piece of copper with a thickness of 18 μm at each side) manufactured by Mitsubishi Gas Chemical Company, Inc. was surface treated using a finishing agent “MEC Etch Bond CZ-8100” (trade name) manufactured by MEC Co., Ltd. to be used as the copper-clad laminate. Measurement results of the number of defects and the number of cracks generated due to the thermal shock test in the obtained laminated body are shown in Table 2.

TABLE 2

| Example | Ex. 1 | Ex. 2 | Ex. 3 | Ex. 4 | Ex. 5 |
|---|---|---|---|---|---|
| Varnish | A | A | A | B | B |
| Slurry | A | B | C | A | D |
| Viscosity | 1,820 | 1,740 | 1,700 | 1,590 | 1,750 |
| of curable | | | | | |
| varnish | | | | | |
| (mPa · s) | | | | | |
| Number of | 4 | 10 | 5 | 2 | 4 |
| cracks | | | | | |
| Defects | A | A | A | B | A |

### Examples 2 and 3

Laminated bodies were prepared as in Example 1 except that the slurry B or the slurry C was used, respectively instead of the slurry A, and the respective properties thereof were measured. Results are shown in Table 2.

### Example 4

A curable varnish was produced as in Example 1 except that the varnish B obtained in Production Example 3 was used instead of the varnish A. A laminated body was produced using this curable varnish as in Example 1 and the respective properties thereof were measured. Results are shown in Table 2.

### Example 5

A laminated body was produced as in Example 4 except that the slurry D was used instead of the slurry A and the respective properties thereof were measured. Results are shown in Table 2.

### Comparative Examples 1 and 2

A laminated body was produced as in Example 1 except that the slurry E or the slurry F was used, respectively instead of the slurry A and the respective properties thereof were measured. Results are shown in Table 3.

TABLE 3

Comparative Example

| | Comp. | Comp. | Comp. | Comp. |
|---|---|---|---|---|
| | Ex. 1 | Ex. 2 | Ex. 3 | Ex. 4 |
| Varnish | A | A | B | B |
| Slurry | E | F | E | F |
| Viscosity | 1,650 | 6,830 | 1,570 | 5,920 |
| of curable | | | | |
| varnish | | | | |
| (mPa · s) | | | | |
| Number of | 55 | 138 | 48 | 119 |
| cracks | | | | |
| Defects | A | A | A | A |

### Comparative Examples 3 and 4

A laminated body was produced as in Example 4 except that the slurry E or the slurry F was used, respectively instead of the slurry A and the respective properties thereof were measured. Results are shown in Table 3.

From the above results, it is apparent that the curable resin composition of the present invention had an inorganic filler that was favorably dispersed, and that the laminated body obtained by using the curable resin composition had few defects and also was excellent in terms of thermal shock resistance (Examples 1 to 5). On the other hand, when the molecular weight of the treating agent used in the surface treatment was too low, thermal shock resistance was insufficient (Comparative Examples 1 and 3). Moreover, when the silica that was not subjected to the surface treatment was used as an inorganic filler, the dispersion of inorganic filler was insufficient and thermal shock resistance also impaired even further (Comparative Examples 2 and 4).

1. A curable resin composition comprising:
an insulating polymer;
a curing agent; and
an inorganic filler;
wherein the inorganic filler is silica particles whose surface is bound with 0.1 to 30% by weight, based on the weight of the silica particles, of an alkoxy group-containing silane-modified resin (I) whose weight average molecular weight is 2,000 or more.

2. The curable resin composition according to claim 1, wherein the alkoxy group-containing silane-modified resin (I) is an alkoxy group-containing silane-modified epoxy resin.

3. The curable resin composition according to claim 1, wherein the insulating polymer is an alicyclic olefin polymer.

4. The curable resin composition according to claim 1, wherein the inorganic filler is the silica particles to which the alkoxy group-containing silane-modified resin is bound using a wet dispersion method.

5. The curable resin composition according to claim 1, which is a varnish formed by further containing an organic solvent.

6. A shaped material formed by shaping the curable resin composition according to claim 1.

7. The shaped material according to claim 6 that is film-shaped or sheet-shaped.

8. A method for producing a shaped material, comprising a step of applying the curable resin composition according to claim 5 on a support and drying it.

9. A cured material formed by curing the shaped material according to claim 6.

10. A laminated body formed by laminating a substrate having a conductor layer on its surface and an electrically insulating layer containing the cured material according to claim 9.

11. A method for producing a laminated body, comprising a step of thermally compressing and curing the shaped material according to claim 6 on a substrate having a conductor layer on its surface to form an electrically insulating layer.

12. A multilayer printed circuit board comprising the laminated body according to claim 10.
